(19) United States
(12) Patent Application Publication
(10) Pub. No.: US 2025/0143046 A1
(43) Pub. Date: May 1, 2025

(54) LIGHT EMITTING DIODE PACKAGE STRUCTURE AND LEAD FRAME FOR THE SAME

(71) Applicant: LITE-ON TECHNOLOGY CORPORATION, TAIPEI CITY (TW)

(72) Inventors: HSIN-HUI LIANG, Taoyuan City (TW); CHENG-HONG SU, Taipei City (TW); CHEN-HSIU LIN, NEW TAIPEI CITY (TW); CHIH-LI YU, New Taipei City (TW); CHENG-HAN WANG, New Taipei City (TW); SHENG-YUN WANG, New Taipei City (TW)

(21) Appl. No.: 18/926,327

(22) Filed: Oct. 25, 2024

Related U.S. Application Data
(60) Provisional application No. 63/545,969, filed on Oct. 27, 2023.

(30) Foreign Application Priority Data
Aug. 23, 2024 (CN) 202422049096.2

(51) Int. Cl. H01L 33/62; H01L 33/52

(52) U.S. Cl. CPC H10H 20/857; H10H 20/852

(57) ABSTRACT

A light emitting diode package structure includes one or more lead frame units, a light emitting element, and an encapsulation unit that completely covers the light emitting element and partially covers the lead frame units. Each lead frame unit includes a chip-mounted portion, a first electrode portion, and a second electrode portion. The first and the second electrode portion extend along a first direction, and are disposed on two sides of the chip-mounted portion. Each lead frame unit further includes multiple first connecting portions extending from the chip-mounted portion along the first direction, and multiple second connecting portions formed by extension of the first and the second electrode portion along a second direction. The light emitting element is fixed to the chip-mounted portion and electrically connected to the electrode portions. A lead frame that includes the at least one lead frame unit is also provided.

### CROSS-REFERENCE TO RELATED PATENT APPLICATION

This application claims the benefit of priority to the U.S. Provisional Patent Application Ser. No. 63/545,969, filed on Oct. 27, 2023, and China Patent Application No. 202422049096.2, filed on Aug. 23, 2024, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light emitting diode (LED) package structure and a lead frame for the LED package structure, and more particularly to an LED package structure that includes a lead frame for allowing a light emitting diode (LED) chip to be mounted thereon and a lead frame that has an improved structure and is provided for the LED package structure.

### BACKGROUND OF THE DISCLOSURE

An LED package structure is highly dependent on the design of an internal lead frame unit. The structure of the lead frame unit can affect electrodes of the LED package structure, the stability of its internal structure, and even the waterproof performance. In the conventional technology, multiple lead frame units having the same structure are formed from a sheet-shaped metallic lead frame. After a cutting process, the lead frame units are separated, and the individual lead frame unit can be obtained. During the cutting process, whether or not the connection structure between the lead frame units is stable also needs to be taken into consideration.

The LED package structure may include a single LED chip or multiple LED chips. Different LED chips usually need to be electrically controlled in a separate manner. However, separate electrical controlling of the LED chips is limited by the structural arrangement of the lead frame units in the LED package structure.

Currently, since the electrodes of the multiple LED chips of the LED package structure need to be electrically independent from one another, the lead frame for the LED package structure having the single LED chip is not suitable for the lead frame for the LED package structure having the multiple LED chips. It is more difficult to apply the lead frame for the LED package structure having the single LED chip to the LED package structure having the multiple LED chips that are arranged in a matrix. The LED package structure with a different number of the LED chips often requires a different lead frame.

Therefore, how to enable one lead frame to be applicable to LED package structures with different numbers of LED chips through improvements in the structural design of the lead frame, so as to enhance the manufacturing efficiency of the LED package structures and overcome the above-mentioned problems, has become one of the issues to be solved in this technical field.

### SUMMARY OF THE DISCLOSURE

In response to the above-referenced technical inadequacies, the present disclosure provides a lead frame for a light emitting diode (LED) package structure that is suitable for the LED package structure with different numbers of LED chips.

In order to solve the above-mentioned problems, one of the technical aspects adopted by the present disclosure is to provide a lead frame for an LED package structure, which includes one or more lead frame units. Each of the lead frame units includes a chip-mounted portion, a first electrode portion, and a second electrode portion. The first electrode portion and the second electrode portion are oppositely disposed on two sides of the chip-mounted portion. The lead frame unit further includes a plurality of first connecting portions, and a plurality of second connecting portions. The plurality of first connecting portions are oppositely formed on different sides of the chip-mounted portion along a first direction, so as to cross-connect the chip-mounted portions of an adjacent one of the lead frame units. The second connecting portions are respectively formed by extension of the first electrode portion and the second electrode portion along a second direction, so as to cross-connect the second connect portion of an adjacent one of the lead frame units. The first direction is perpendicular to the second direction. The first electrode portion and the second electrode portion are disposed opposite to each other on different sides of the chip-mounted portion along the second direction.

In order to solve the above-mentioned problems, another one of the technical aspects adopted by the present disclosure is to provide a light emitting diode structure, which includes one or more lead frame units, a light emitting element, and an encapsulation unit. Each of the lead frame units includes a chip-mounted portion, a first electrode portion, and a second electrode portion. The first electrode portion and the second electrode portion are extended along a first direction and oppositely disposed on two sides of the chip-mounted portion. Each of the lead frame units further includes a plurality of first connecting portions and a plurality of second connecting portions. The first connecting portions extend from different sides of the chip-mounted portion that are opposite to each other along the first direction, so as to cross-connect the chip-mounted portion of an adjacent one of the lead frame units. The second connecting portions are formed by extension of the first electrode portion and the second electrode portion along the second direction to cross-connect the second connecting portions of an adjacent one of the lead frame units. The first direction is perpendicular to the second direction. The light emitting element is fixed to the chip-mounted portion and electrically connected to the first electrode portion and the second electrode portion. The encapsulation unit completely covers the light emitting element and partially covers the one or more chip-mounted portions.

Therefore, in the LED package structure and the lead frame for the same provided by the present disclosure, through arrangement and connection ways of the first connecting portions and the second connecting portions of the lead frame unit, more than two lead frame units can be connected in a parallel manner, or four lead frame units can be arranged in a 2×2 matrix. Furthermore, electrodes of each lead frame unit can be electrically independent from one another, so as not to affect each other. Accordingly, in the LED package structure of the present disclosure, the light emitting elements on the chip-mounted portions can be independently controlled.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a top view of a lead frame for a light emitting diode package structure according to the present disclosure;

FIG. 2 is a top perspective view of one single lead frame unit according to the present disclosure;

FIG. 3 is a bottom perspective view of one single lead frame unit according to the present disclosure;

FIG. 4 is a top view of two lead frame units connected in parallel according to the present disclosure;

FIG. 5 is a top view of three lead frame units connected in parallel according to the present disclosure;

FIG. 6 is a top view of four lead frame units connected in a matrix form according to the present disclosure;

FIG. 7 to FIG. 9A are schematic views showing processes of manufacturing the light emitting diode package structure according to the present disclosure;

FIG. 9B is a schematic cross-sectional view of the light emitting diode package structure having a lens of another embodiment according to the present disclosure;

FIG. 10A is a schematic cross-sectional view of the light emitting diode package structure having a light-shielding layer according to the present disclosure;

FIG. 10B is a schematic cross-sectional view of the light emitting diode package structure having a light-shielding layer of another embodiment according to the present disclosure;

FIG. 10C is a schematic cross-sectional view of the light emitting diode package structure having an opaque base according to the present disclosure;

FIG. 11 is a schematic view of the light emitting diode package structure after being cut according to the present disclosure;

FIG. 12 is a perspective view of the light emitting diode package structure with a single lead frame unit according to the present disclosure;

FIG. 13 is a perspective view of the light emitting diode package structure with two lead frame units according to the present disclosure;

FIG. 14 is a perspective view of the light emitting diode package structure with three lead frame units according to the present disclosure; and

FIG. 15 is a perspective view of the light emitting diode package structure with four lead frame units according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present creation, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

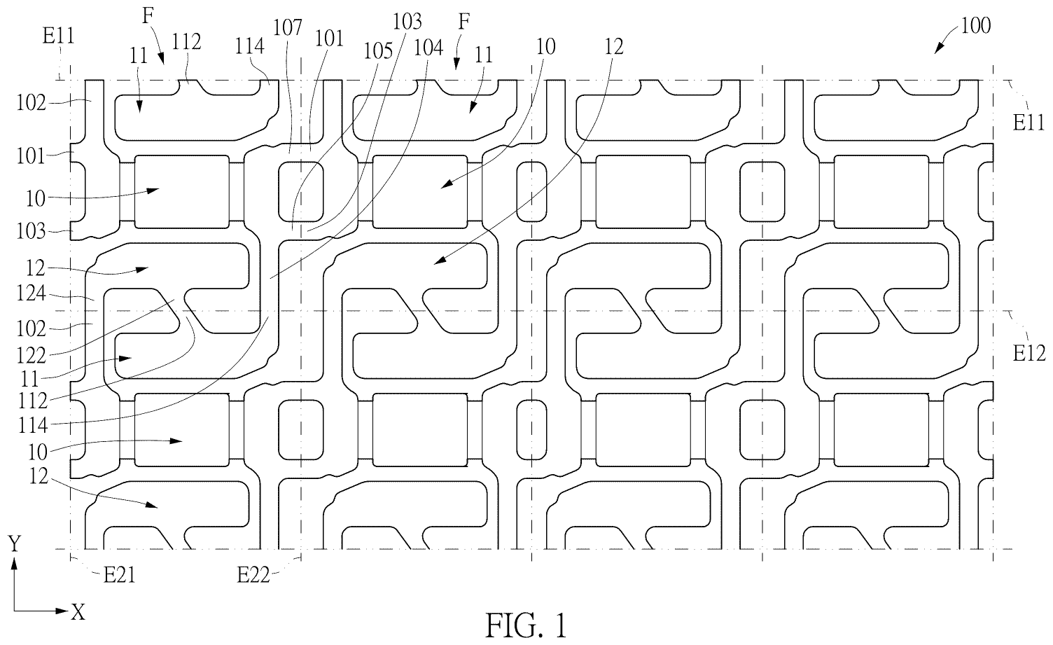

Referring to FIG. 1 to FIG. 5, a first embodiment of the present disclosure provides a lead frame 100 for an LED, which is made of a sheet metal by etching or stamping and other processing steps. The lead frame 100 can be cut into multiple lead frame units F. In addition, the lead frame 100 of the present embodiment can be cut into more than two lead frame units F connected in parallel. Each lead frame unit F includes a chip-mounted portion 10, a first electrode portion 11, and a second electrode portion 12. The first electrode portion 11 and the second electrode portion 12 are disposed opposite to each other on different sides of the chip-mounted portion 10. Each lead frame unit F further includes a plurality of first connecting portions (101, 103, 105, 107), and a plurality of second connecting portions (102, 112, 114, 104, 122, 124).

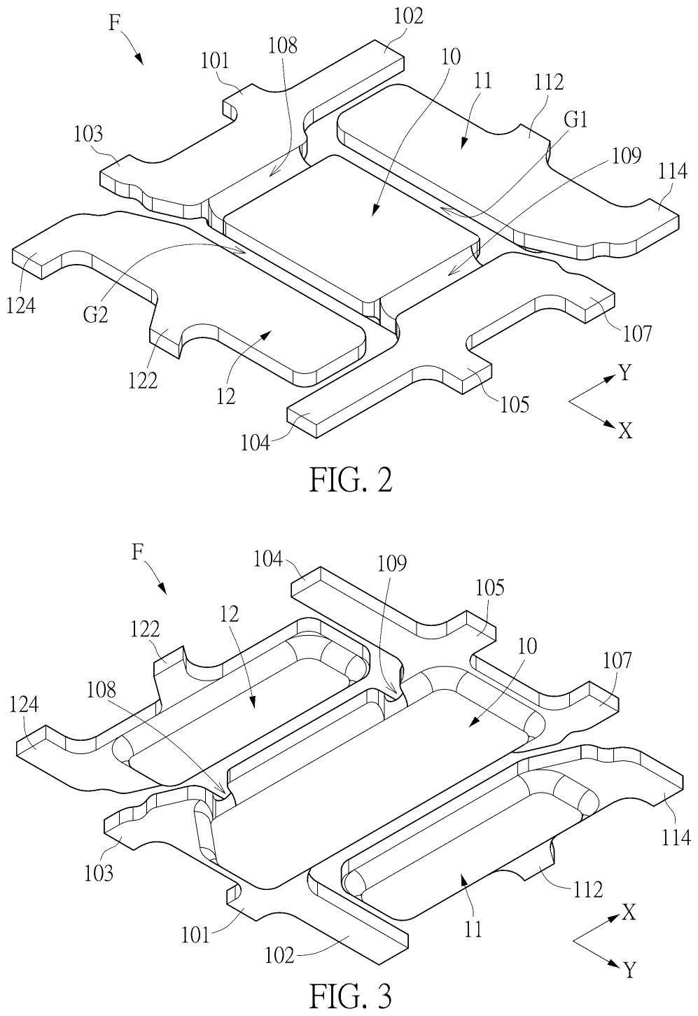

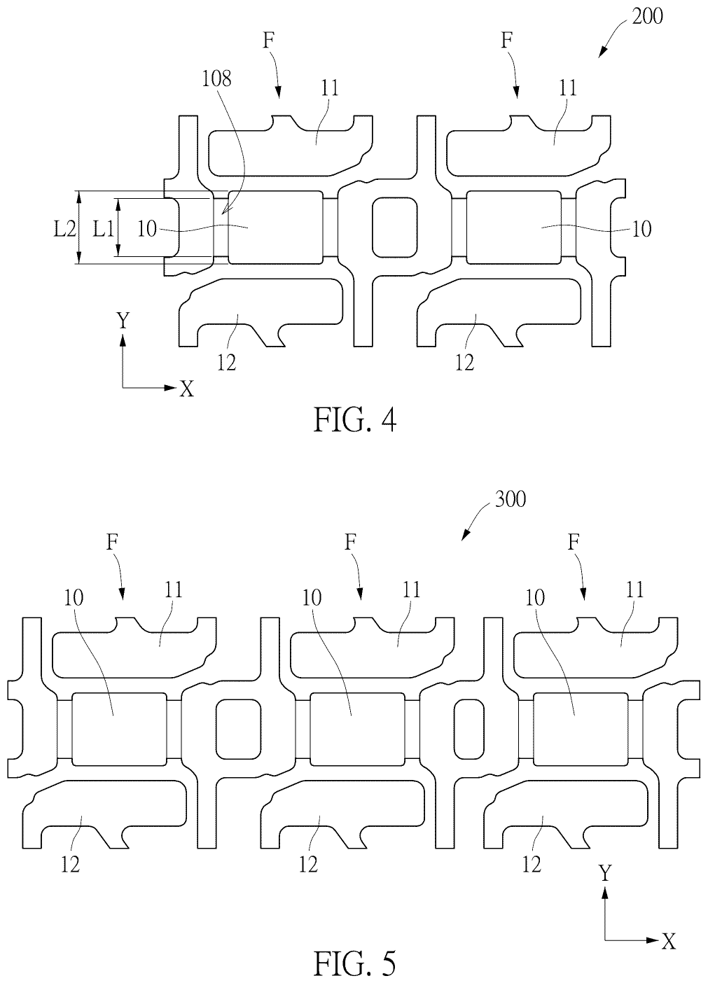

Referring to FIGS. 2 and 3, in this embodiment, the chip-mounted portion 10, the first electrode portion 11, and the second electrode portion 12 are shaped substantially in a narrow and elongated plate, with a longitudinal direction substantially parallel to the first direction (i.e., the X-axis direction of the coordinate axis, which is hereinafter labeled as X). In addition, the first electrode portion 11 and the second electrode portion 12 are oppositely located on different sides of the chip-mounted portion 10. The first electrode portion 11 and the second electrode portion 12 are positioned on different sides of the chip-mounted portion 10. The first direction X is perpendicular to the second direction Y.

Referring to FIG. 1, in this embodiment, the lead frame unit F is defined with two first boundaries E11, E12 parallel to the first direction X, and two second boundaries E21, E22 parallel to the second direction Y.

Referring to FIG. 1, in this embodiment, a plurality of first connecting portions (101, 103, 105, 107) are formed by the opposite sides of the chip-mounted portion 10 extending opposite in the first direction X to cross-connect the chip-mounted portion 10 of an adjacent one of the lead frame units F. In the present embodiment, the chip-mounted portion 10 has two sides parallel to the first direction X (or transverse side), and two sides parallel to the second direction Y (or longitudinal side). In detail, the chip-mounted portion 10 has two first connecting portions (101, 103) in one longitudinal side parallel to the second direction Y, and the chip-mounted portion 10 has two first connecting portions (105, 107) in the other longitudinal side parallel to the second direction Y. The first connecting portion 101 cross-connects the first connecting portion 107 of an adjacent one of the lead frame units F, and the first connecting portion 103 cross-connects the first connecting portion 105 of an adjacent one of the lead frame units F.

Multiple second connecting portions (102, 112, 114, 104, 122, 124) are formed by the first electrode portion 11, the second electrode portion 12, respectively, extending along the second direction Y to cross-connect the second connecting portions (124, 122, 104, 114, 112, 102) of an adjacent one of the lead frame units F. The second connecting portions (102, 112, 114, 104, 122, 124) are divided into a first group and a second group of equal number. The plurality of second connecting portions (102, 112, 114) of the first group extends across one of the first boundary E11 for connecting an adjacent lead frame unit. Multiple second connecting portions (104, 122, 124) of the second group extend across another of the first boundary E12 to connect an adjacent one of the lead frame units.

Referring to FIGS. 2 and 3, specifically, the first group has three second connecting portions (102, 112, 114). Two outer ones of second connecting portions (102, 114) are extended along a direction parallel to the second direction Y. In the same lead frame unit F, the second connecting portion 102 is electrically isolated from the second connecting portion 114. In other words, the second connecting portion 102 is connected to the first connecting portions (101, 103) and the other second connecting portion 114 is connected to the first electrode portion 11. In particular, a third one of the second connecting portion 112 is connected to the first electrode portion 11. In other words, the first electrode portion 11 is connected to two second connecting portions 112, 114 along the positive Y-axis direction. The second connecting portion 114 extends from one end of the first electrode portion 11, and the second connecting portion 112 extends from the middle of the first electrode portion 11, so that the connection of the first electrode portion 11 and the second connecting portions 112, 114 is similarly in an F-shape. The second connecting portion 112 is located approximately in the middle of the second connecting portion 102 and the second connecting portion 114. In the present embodiment, the second connecting portion 112 extends along the second direction Y and is slightly inclined to the first direction X. However, the present disclosure is not limited thereto.

Specifically, the second group has three of the second connecting portions (104, 122, 124). Two outer ones of the second connecting portions (104, 124) extend along a direction parallel to the second direction Y. In the same lead frame unit F, the second connecting portion 104 is electrically isolated from the second connecting portion 124. In other words, the second connecting portion 104 is connected to the first connecting portion (105, 107), and the other second connecting portion 124 is connected to the second electrode 12. In particular, a third one of the second connecting portion 122 is connected to the middle portion of the second electrode portion 12. In other words, the second electrode portion 12 is connected along the negative Y-axis direction with two second connecting portions 122, 124. The second connecting portion 124 extends from one end of the second electrode portion 12. The second connecting portion 122 extends from the middle portion of the second electrode portion 12 and is connected in a similar F-shape. The second connecting portion 122 is located approximately in the middle of the second connecting portion 104 and the second connecting portion 124. In the present embodiment, the second connecting portion 122 extends along the second direction Y and is slightly inclined to the first direction X. However, the present disclosure is not limited thereto.

Referring to FIGS. 2 and 3, two of the second connecting portions 102, 104 are connected to opposite corners of the chip-mounted portion 10 and parallel to the second direction Y. Specifically, each of the two opposite corners of the chip-mounted portion 10 is connected to a second connecting portion 102 through a first connecting portion 101 and to a second connecting portion 104 through another first connecting portion 105.

Referring to FIG. 1, the second connecting portions (102, 112, 114) of the first group are evenly distributed at the first boundary E11 of the lead frame unit F, and the second connecting portions (104, 122, 124) of the second group are evenly distributed at the other first boundary E12 of the lead frame unit F. Therefore, the cutting and molding stresses of the lead frame unit F can be uniformly distributed.

However, the present disclosure is not limited thereto. Two sides of each chip-mounted portion 10 are connected to at least one first connecting portion, which may be positioned at the first connecting portion (101, 105), or at the first connecting portion (103, 107), or at the middle of the sides of the chip-mounted portion 10. The at least one first connecting portion extends across the second boundary E21, E22 to connect to an adjacent chip-mounted portion 10.

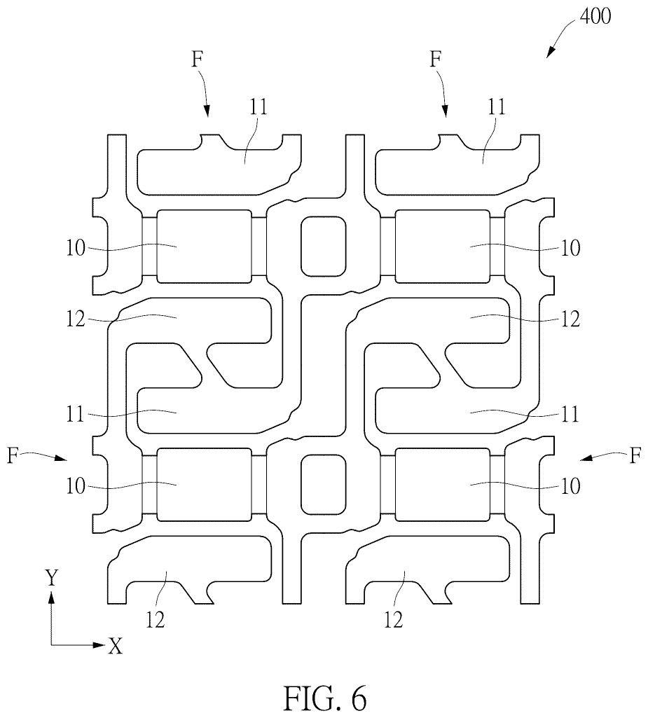

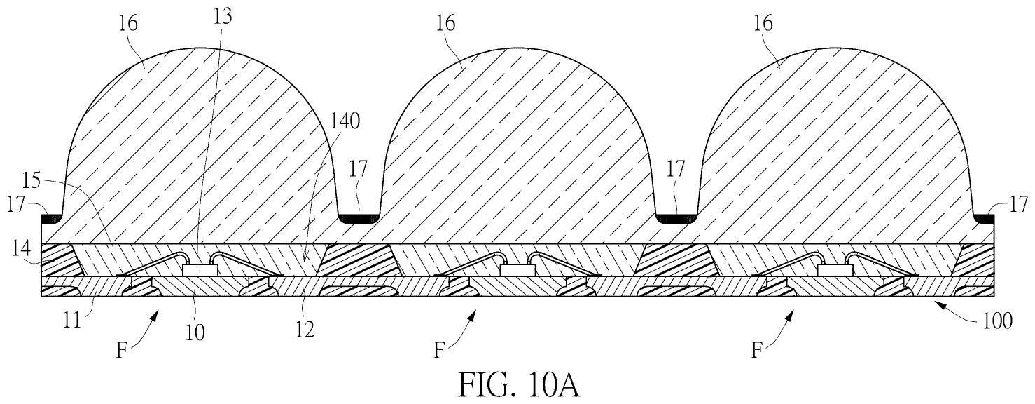

Referring to FIGS. 2 and 4, incidentally, two sides of the chip-mounted portion 10 are respectively formed with a groove portion 108, 109 adjacent to the first connecting portion (101, 103, 105, 107). A length L1 of the groove portion 108, 109 in the longitudinal direction (Y-direction, as shown in FIG. 4) are both less than a side length L2 of a connecting edge of the chip-mounted portion 10 correspondingly connected therewith. A slit G1 is formed between the chip-mounted portion 10 and the first electrode portion 11, and another slit G2 is formed between the chip-mounted portion 10 and the second electrode portion 12. The groove portions 108, 109 are formed so that the top surface of the chip-mounted portion 10 is not continuously connected to the top surface of the first electrode portion 11, and the top surface of the chip-mounted portion 10 is not continuously connected to the top surface of the second electrode portion 12. Accordingly, after the subsequent package process, the probability of moisture approaching the chip-mounted portion 10 through the slit between the encapsulation unit (15, as shown in FIG. 8, which will be described in detail later) and the first electrode portion 11 or the second electrode portion 12 is reduced. The groove portions 108, 109 can extend a path of moisture from the outside to the chip-mounted portion 10, so as to reduce the risk of moisture permeating into the chip-mounted portion 10. At the same time, the groove portions 108, 109 can enhance the bonding strength of between the encapsulation unit and the lead frame unit F.

One side of the chip-mounted portion 10 has two first connecting portions 101, 103 that are connected to the groove portion 108 to form a U-shape. The other side of the chip-mounted portion 10 has two first connecting portions 105, 107 that are connected to the groove portion 109 to form a U-shape.

Referring to FIGS. 2 and 3, in one of the lead frame units F, the first electrode portion 11 is connected to two of the second connecting portions 112, 114, thus forming an F-shape. The second electrode portion 12 is connected to two of the second connecting portions 122, 124, thus forming an F-shape. On one side of the chip-mounted portion 10, the two first connecting portions 101, 103 are connected to the second connecting portion 102, thus forming an F-shape. On the other side of the chip-mounted portion 10, the two first connecting portions 105, 107 are connected to the second connecting portion 104, thus forming an F-shape.

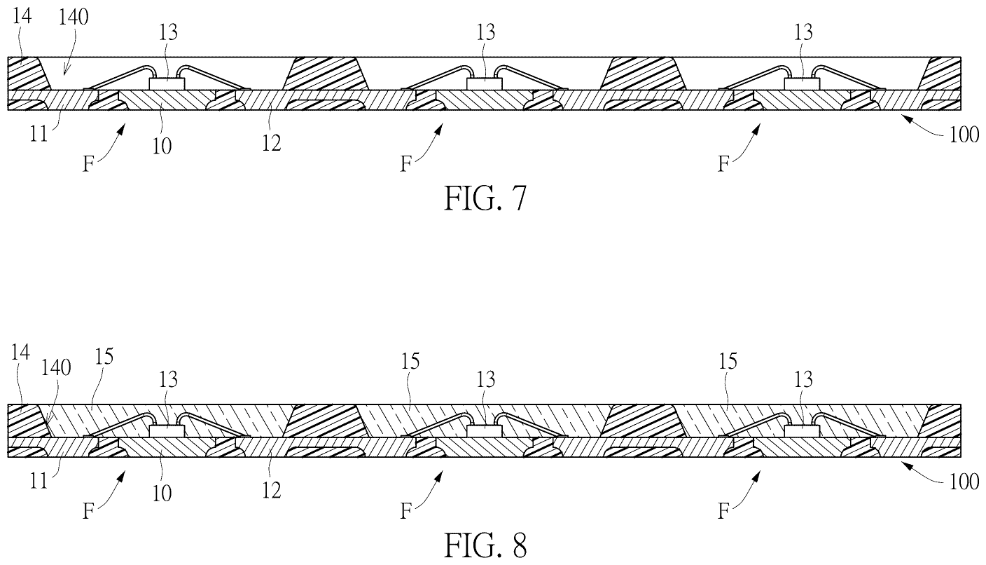

Referring to FIGS. 4 to 5, by utilizing the aforementioned structural arrangement, the lead frame 100 for the light-emitting diode is configured to be cut so that it can be formed into one or more single-row connected lead frame units F along the first direction X. The lead frame assembly 200 as shown in FIG. 4 has two lead frame units F along the first direction X. The lead frame assembly 300 as shown in FIG. 5 has three lead frame units F along the first direction X.

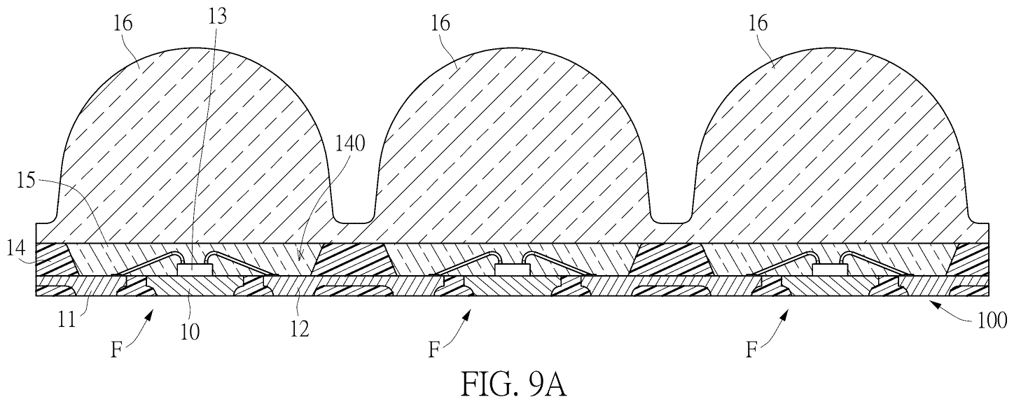

Referring to FIG. 6, by utilizing the aforementioned structural arrangement, the lead frame assembly 400 of the light-emitting diode is configured in a 2×2 matrix arrangement of four lead frame units F. Moreover, it is worth noting that the first electrode portion 11 and the second electrode portion 12 of each of the lead frame units F of the above-mentioned lead frame assembly can be electrically independent from one another after cutting. The first electrode portion 11 and the second electrode portion 12 near the center along the second direction Y can be connected to the same polarity, such as positive. The uppermost first electrode portion 11 and the lowermost second electrode portion 12 can be connected to the same polarity, such as negative. In this way, the lead frame 100 of the present disclosure for the light emitting diode can provide multiple parallel connections of the lead frame unit F through the above unique structural design of the lead frame unit F. There is no need to redesign the structure of the lead frame for different requirements, which enhances the adaptability to be possible and saves cost.

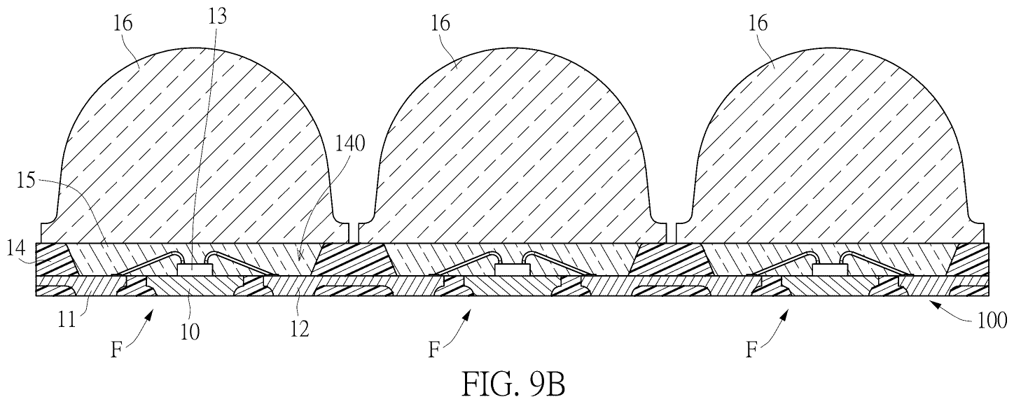

Referring to FIGS. 7 to 11, the manufacturing process of the light emitting diode (LED) package structure 100E of the present disclosure is illustrated. Each schematic cross-sectional view is illustrated parallel to the second direction and taken along a middle of the chip-mounted portion 10. Referring to FIG. 7, the lead frame 100 is illustrated with three lead frame units F, which are filled with an opaque base 14. In this embodiment, the base 14 partially protrudes from the top surface of the lead frame 100 to form a plurality of bowl-shaped accommodating spaces 140. Each of the lead frame units F is provided with a light emitting element 13 that is fixed to the top surface of the chip-mounted portion 10. The light emitting element 13 may be a light emitting diode (LED) chip in this embodiment, but is not limited thereto. The light emitting element 13 is electrically connected to the first electrode portion 11 and the second electrode portion 12 by wires.

Referring to FIG. 8, an encapsulation unit 15 is filled in the accommodating space 140. The encapsulation unit 15 can be, for example, a transparent resin, and mixed with fluorescent powder. The encapsulation unit 15 completely covers the light emitting element 13 and partially covers the lead frame unit F. In this example, the top surface of the encapsulation unit 15 is flat and flush with a partially-protruded portion of the base 14.

In another embodiment, due to the surface tension effect when filling the encapsulation unit 15, and depending on the amount of the encapsulation unit 15, the top surface of the encapsulation unit 15 is curved and is substantially protruded from or depressed below the partially-protruded portion of the base 14.

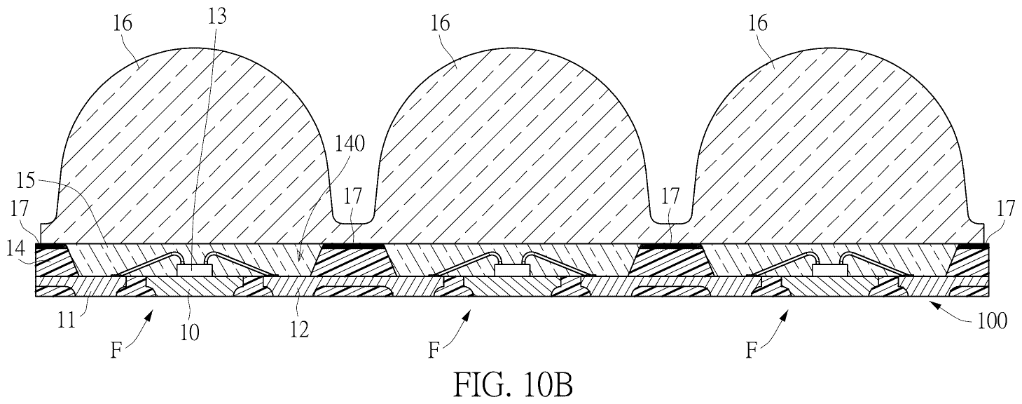

Referring to FIG. 9A of one embodiment, a lens layer with a plurality of lens portions 16 is formed on the encapsulation unit 15 and covers the base 14. The lens portions 16 in this embodiment are shaped in convex lenses and respectively correspond to the encapsulation units 15.

Referring to FIG. 9B of another embodiment, a plurality of lens portions 16 are respectively formed on the encapsulation units 15 and cover the base 14. The lens portions 16 of this embodiment are shaped in convex lenses, separated away from each other without connection, and respectively corresponded to the encapsulation units 15.

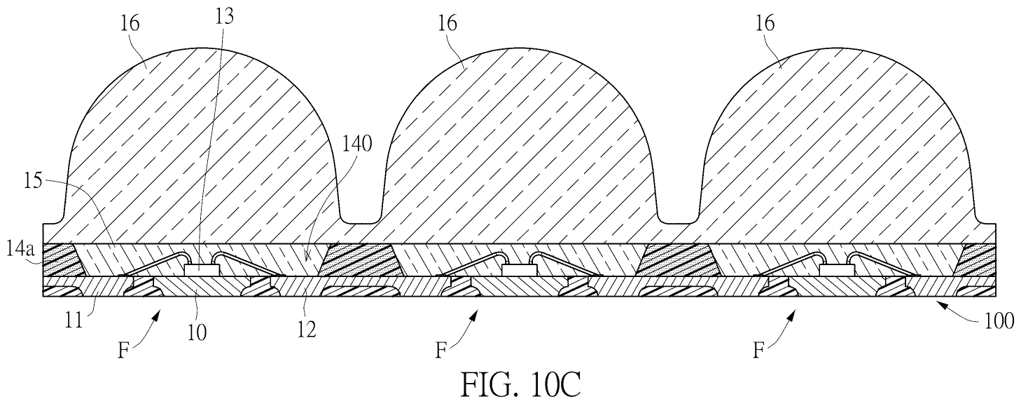

Referring to FIG. 10A of one embodiment, a light-shielding layer 17 is applied around the lens portion 16. For example, the light-shielding layer 17 is a dark-colored opaque adhesive to block stray light from being emitted from areas other than the lens portion 16 and to increase the contrast between the lead frame 100 and the lens portion 16.

Referring to FIG. 10B of another embodiment, a light-shielding layer 17 is applied to an upper edge of the base 14. The light-shielding layer 17 is, for example, a dark opaque gel or dark opaque paint to increase the visual contrast between the lead frame 100 and the lens portion 16.

Referring to FIG. 10C of a further embodiment, the base 14a is formed with a dark opaque material, such as epoxy resin, polyurethane, silicone, or other dark opaque material, to increase the visual contrast between the lead frame 100 and the lens portion 16.

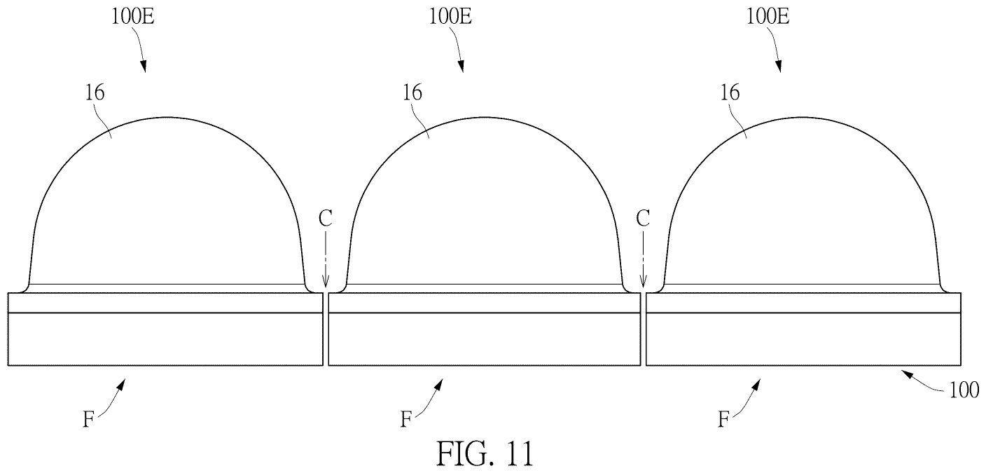

Referring to FIG. 11, a cutting step is performed by cutting a cutting line C between two of the lens portions 16 according to the desired range.

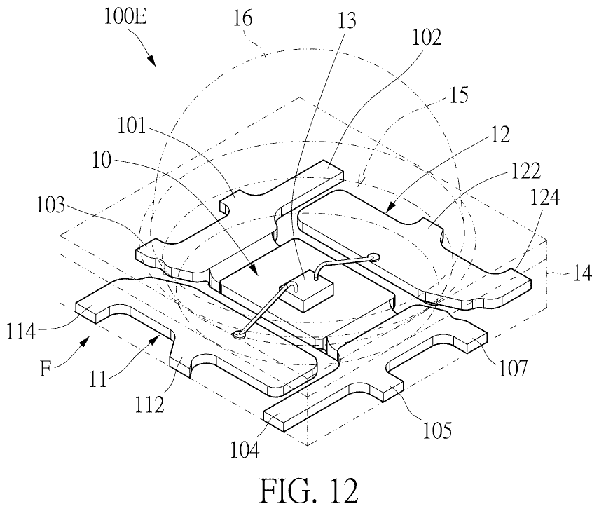

Referring to FIG. 12, after cutting in this embodiment, the light-emitting diode (LED) package structure 100E includes only one lead frame unit F. The LED package structure 100E includes one lead frame unit F of the lead frame 100, one light emitting element 13, one encapsulation unit 15, and one lens portion 16. It is also noted that some of the LED package structures 100E do not require a lens portion. In particular, the connection relationship between the plurality of first connecting portions and the plurality of second connecting portions of each lead frame unit F is the same as that described in FIGS. 1 to 6 and applied to FIGS. 7 to 15.

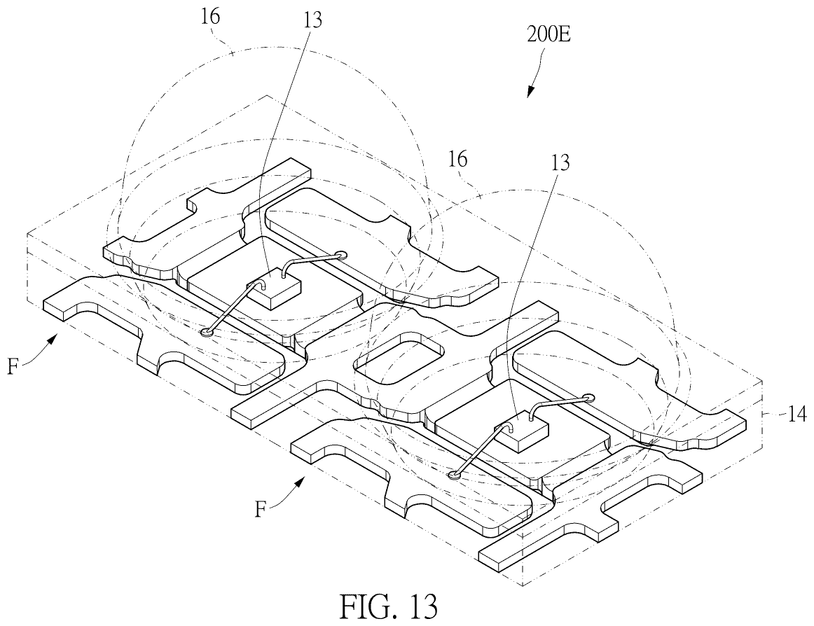

Referring to FIG. 13, after cutting in this embodiment, the light emitting diode (LED) package structure 200E includes two lead frame units F of the lead frame 100 arranged along a first direction X. As described above, each lead frame unit F includes a chip-mounted portion 10, a first electrode portion 11, and a second electrode portion 12. The first electrode portion 11 and the second electrode portion 12 are disposed on opposite sides of the chip-mounted portion 10. The multiple electrode portions of the two lead frame units F can be electrically independent from each other so that each light emitting element 13 can be controlled separately.

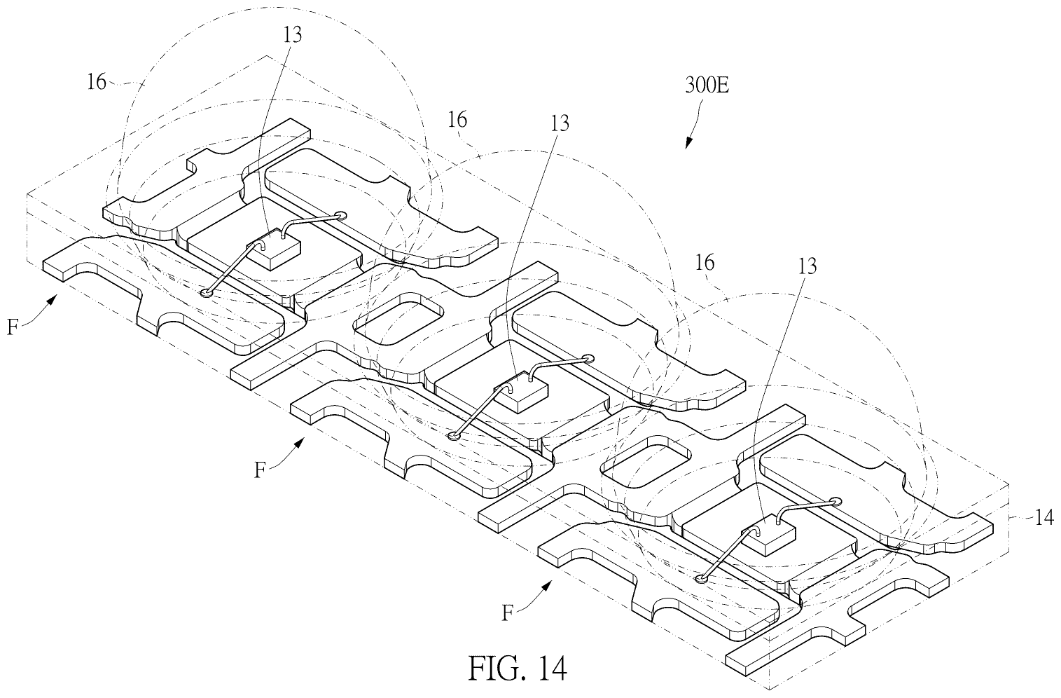

Referring to FIG. 14, after cutting in this embodiment, the light emitting diode (LED) package structure 300E includes three lead frame units F of the lead frame 100 arranged along a first direction X. As described above, each lead frame unit F includes a chip-mounted portion 10, a first electrode portion 11, and a second electrode portion 12. The first electrode portion 11 and the second electrode portion 12 are located on opposite sides of the chip-mounted portion 10. The electrodes of the three lead frame units F can be electrically independent from each other so that each light emitting element 13 can be controlled separately.

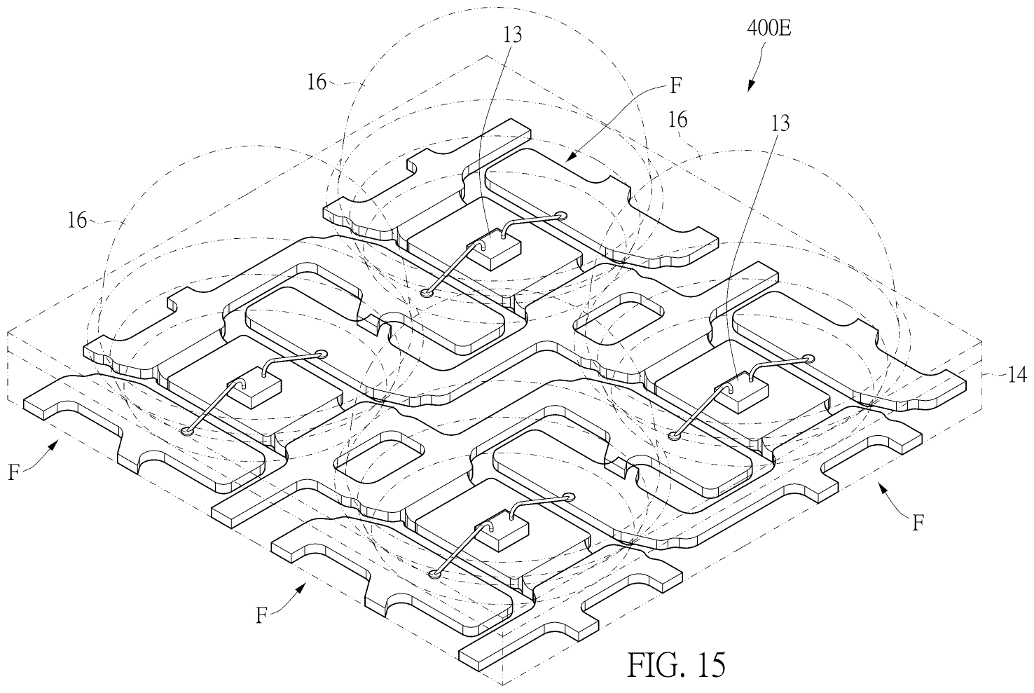

Referring to FIG. 15, after cutting in this embodiment, the light emitting diode (LED) package structure 400E includes four lead frame units F of the lead frame 100 arranged in a 2×2 matrix. There are two lead frame units F arranged along the first direction X, and two lead frame units F arranged along the second direction Y. Similarly, each lead frame unit F includes a chip-mounted portion 10, a first electrode portion 11, and a second electrode portion 12. The first electrode portion 11 and the second electrode portion 12 are disposed on opposite sides of the chip-mounted portion 10. Multiple electrodes of the four lead frame units F can be electrically independent from each other, so that each light emitting element 13 can be controlled separately.

### Beneficial Effects of the Embodiment

In conclusion, the beneficial effects of the present disclosure are that, in the LED package structure and the lead frame for the same provided by the present disclosure, through arrangement and connection ways of the first connecting portions and the second connecting portions of the lead frame unit, more than two lead frame units can be connected in a parallel manner, or four lead frame units can be arranged in a 2×2 matrix. Furthermore, electrodes of each lead frame units can be electrically independent and from one another so as not to affect each other. Therefore, the lead frame for the LED package structure having the single LED chip can be suitable for the LED package structure having multiple LED chips. Accordingly, in the LED package structure of the present disclosure, one or more light-emitting elements on the chip-mounted portions can be independently controlled.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A lead frame for a light emitting diode package structure, comprising:
one or more lead frame units, wherein each of the lead frame units includes a chip-mounted portion, a first electrode portion, and a second electrode portion, and the first electrode portion and the second electrode portion are oppositely disposed on two sides of the chip-mounted portion; wherein the lead frame unit further includes:
a plurality of first connecting portions, wherein the first connecting portions are oppositely formed on different sides of the chip-mounted portion along a first direction, so as to cross-connect the chip-mounted portion of an adjacent one of the lead frame units; and
a plurality of second connecting portions, wherein the second connecting portions are formed by extension of the first electrode portion and the second electrode portion along a second direction, so as to cross-connect the second connecting portion of an adjacent one of the lead frame units;
wherein the first direction is perpendicular to the second direction, and the first electrode portion and the second electrode portion are disposed opposite to each other on different sides of the chip-mounted portion along the second direction.

2. The lead frame according to claim 1, wherein the lead frame is cuttable for forming the one or more lead frame units that are connected in a single row along the first direction, or the lead frame units that are arranged in a 2×2 matrix; wherein the first electrode portion and the second electrode portion of each of the lead frame units are independent and electrically isolated from each other.

3. The lead frame according to claim 2, wherein each of the lead frame units is defined to have two first boundaries parallel to the first direction and two second boundaries parallel to the second direction, and the second connecting portions are divided into a first group and a second group in equal numbers;
wherein the second connecting portions of the first group extend across one of the first boundaries to connect an adjacent one of the lead frame units;
wherein the second connecting portions of the second group extend across another one of the first boundaries to connect another adjacent one of the lead frame units.

4. The lead frame according to claim 3, wherein the first group includes three of the second connecting portions, two outer ones of the second connecting portions are parallel to the second direction and are separately connected to the first electrode portion and one of the first connecting portions, and a third one of the second connecting portions is connected to middle of the first electrode portion;
wherein the second group includes three of the second connecting portions, two outer ones of the second connecting portions are parallel to the second direction and are separately connected to the second electrode portion and one of the first connecting portions, and the third one of the second connecting portions is connected to middle of the second electrode portion.

5. The lead frame according to claim 3, wherein each of the chip-mounted portions has two opposite corners, and each of the two opposite corners is connected to one of the second connecting portions through one of the first connecting portions.

6. The lead frame according to claim 3, wherein each of the chip-mounted portions has two sides that are each connected to at least one of the first connecting portions, and each of the first connecting portions extends across the second boundary to connect with an adjacent one of the chip-mounted portions.

7. The lead frame according to claim 3, wherein each of the chip-mounted portions has two sides that are each formed with a groove portion adjacent to the first connecting portion, a slit is formed between the chip-mounted portion and the first electrode portion, and another slit is formed between the chip-mounted portion and the second electrode portion.

8. The lead frame according to claim 7, wherein a length of the groove portion is less than a side length of a connecting edge which connects the chip-mounted portion to the groove portion.

9. The lead frame according to claim 7, wherein each of the two sides of the chip-mounted portion respectively has two of the first connecting portions that are connected to the groove portion in a U-shape.

10. The lead frame according to claim 9, wherein, in one of the lead frame units, the first electrode portion is connected to two of the second connecting portions, so as to form an F-shape; wherein the second electrode portion is connected to two of the second connecting portions, so as to form an F-shape; wherein two of the first connecting portions are connected to one of the second connecting portions, so as to form an F-shape.

11. A light emitting diode package structure, comprising:
one or more lead frame units, wherein each of the lead frame units includes a chip-mounted portion, a first electrode portion, and a second electrode portion, and the first electrode portion and the second electrode portion extend along a first direction and are oppositely disposed on two sides of the chip-mounted portion; wherein each of the lead frame units further includes:
a plurality of first connecting portions, wherein the first connecting portions extend from different sides of the chip-mounted portion that are opposite to each other along the first direction, so as to cross-connect the chip-mounted portion of an adjacent one of the lead frame units;
a plurality of second connecting portions, wherein the second connection portions are formed by extension of the first electrode portion and the second electrode portion along a second direction, so as to cross-connect the second connecting portions of an adjacent one of the lead frame units; wherein the first direction is perpendicular to the second direction;
a light emitting element fixed to the chip-mounted portion and electrically connected to the first electrode portion and the second electrode portion; and
an encapsulation unit completely covering the light emitting element and partially covering the one or more lead frame units.

12. The light-emitting diode package structure according to claim 11, wherein the first connecting portions are divided into two groups in equal numbers, and the second connecting portions are divided into two groups in equal numbers.

13. The light-emitting diode package structure according to claim 11, wherein each of the chip-mounted portions has two opposite corners, and each of the two opposite corners is connected to one of the second connecting portions through one of the first connecting portions.

14. The light-emitting diode package structure according to claim 11, wherein each of the chip-mounted portions has two sides that are each formed with a groove portion adjacent to the first connecting portion, a slit is formed between the chip-mounted portion and the first electrode portion, and another slit is formed between the chip-mounted portion and the second electrode portion.

15. The light-emitting diode package structure according to claim 14, wherein a length of the groove portion is less than a side length of a connecting edge which connects the chip-mounted portion to the groove portion.

16. The light-emitting diode package structure according to claim 14, wherein each of the two opposite sides of the chip-mounted portion has two of the first connecting portions that are connected to the groove portion in a U-shape.

17. The light-emitting diode package structure according to claim 11, wherein, in one of the lead frame units, the first electrode portion is connected to two of the second connecting portions, so as to form an F-shape; wherein the second electrode portion is connected to two of the second connecting portions, so as to form an F-shape; wherein two of the first connecting portions are connected to one of the second connecting portions, so as to form an F-shape.
